(19) United States
(12) Patent Application Publication
(10) Pub. No.: US 2003/0087529 A1
(43) Pub. Date: May 8, 2003

(54) Hard mask removal process

(76) Inventors: Yider Wu, Campbell, CA (US); Kouros Ghandehari, Santa Clara, CA (US); Angela Hui, Fremont, CA (US); Jeffrey A. Shields, Sunnyvale, CA (US); Kuo-Tung Chang, Saratoga, CA (US)

Correspondence Address: Joseph A. Sawyer Jr., SAWYER LAW GROUP LLP, P.O. Box 51418, Palo Alto, CA, 94303, US

(21) Appl. No.: 10/039,361

(22) Filed: Nov. 7, 2001

(51) Int. Cl. H01L 21/461; C03C 25/68

(52) U.S. Cl. 438/704; 438/724; 438/757; 216/57

(57) ABSTRACT

A method for removing a hard mask during a semiconductor fabrication process is disclosed in which a hard mask material is used to pattern a first material. The method includes a two-step removal process that includes performing a major wet etch to remove a majority of the hard mask material, followed by performing a minor dry etch that removes a remainder of the hard mask material.

### FIELD OF THE INVENTION

The present invention relates to semiconductor processing, and more particularly to a method for removing a hard mask that is used to pattern another material during semiconductor processing.

### BACKGROUND OF THE INVENTION

During the fabrication of flash memory arrays, a layer of polysilicon referred to as Poly 1 is patterned over a silicon substrate in which lines of oxide insulating regions are embedded. Thereafter, floating gates are formed out of the Poly 1 by etching the Poly 1 over the oxide regions. One goal of the etching process is to etch as little of the Poly 1 away as possible to create spaces as small as possible.

Previous techniques for etching the Poly 1 include depositing a layer photoresist over the layer of Poly 1, and patterning the photoresist using lithographic techniques to form a mask. The photoresist mask is then used to etch the Poly 1 by exposing the uncovered areas of Poly 1 to light. The Poly 1 is etched to form parallel lines of Poly 1 that will be used to form floating gates. Thereafter, the photoresist mask is removed.

Although this technique is effective for etching the Poly 1, the lines of Poly 1 can be patterned no closer than 0.14 microns due to lithographic limitations. For some semiconductor applications, however, such as dense memory arrays, the spacing between the lines of Poly 1 needs to be approximately 0.08-0.05 microns. Currently, this is not possible using lithography.

An improved mask and etch technique has recently been developed for patterning materials during semiconductor fabrication that is capable of surpassing lithographic limitations. This mask and etch technique substitutes a hard mask for a photoresist mask when patterning a material during semiconductor fabrication that allows the smaller spaces in the material to be formed. After the material has been patterned, the hard mask is removed using either a dry etch or a wet etch. Both etch techniques, however, may damage the resulting semiconductor. During flash memory array fabrication, for example, if the hard mask is removed using a dry etch, the oxide regions in the silicon are gouged. Using a wet etch may eliminate the gouging problem, but the wet etch process may erode the surface of Poly 1 and form pits.

Accordingly what is needed is an improved hard mask removal process. The present invention addresses such a need.

### SUMMARY OF THE INVENTION

The present invention provides a method for removing a hard mask during a semiconductor fabrication process in which a hard mask material is used to pattern a first material. The method includes a two-step removal process that includes performing a major wet etch to remove a majority of the hard mask material, followed by performing a minor dry etch that removes the remainder of the hard mask material.

According to the system and method disclosed herein, removing a majority of the hard mask using a wet etch, rather than removing all of the hard mask, prevents the wet etch from damaging the first material. And using a dry etch to remove the remainder of the hard mask substantially eliminates gouging.

### BRIEF DESCRIPTION OF THE DRAWINGS

FIG. 1 is a flow chart illustrating fabrication steps used to pattern Poly 1 into floating gates using a hard mask.

FIGS. 2A-2I are cross-sectional views of the silicon substrate during the fabrication steps described in FIG. 1.

FIGS. 3A and 3B are cross-sectional views of the substrate showing the results of a conventional dry and wet etch, respectively.

FIG. 4 is a flow chart illustrating the processor removing a hard mask in accordance with a preferred embodiment of the present invention.

### DETAILED DESCRIPTION

The present invention relates to a two-step hard mask removal process. The following description is presented to enable one of ordinary skill in the art to make and use the invention and is provided in the context of a patent application and its requirements. Various modifications to the preferred embodiments and the generic principles and features described herein will be readily apparent to those skilled in the art. Thus, the present invention is not intended to be limited to the embodiments shown but is to be accorded the widest scope consistent with the principles and features described herein.

The present invention provides a hard mask removal process for use during semiconductor fabrication. In a preferred embodiment of the present invention, the hard mask removal process is used during the fabrication of flash memory arrays in which Poly 1 is patterned on a silicon substrate using a nitride hard mask that must be removed after the Poly 1 has been patterned into floating gates.

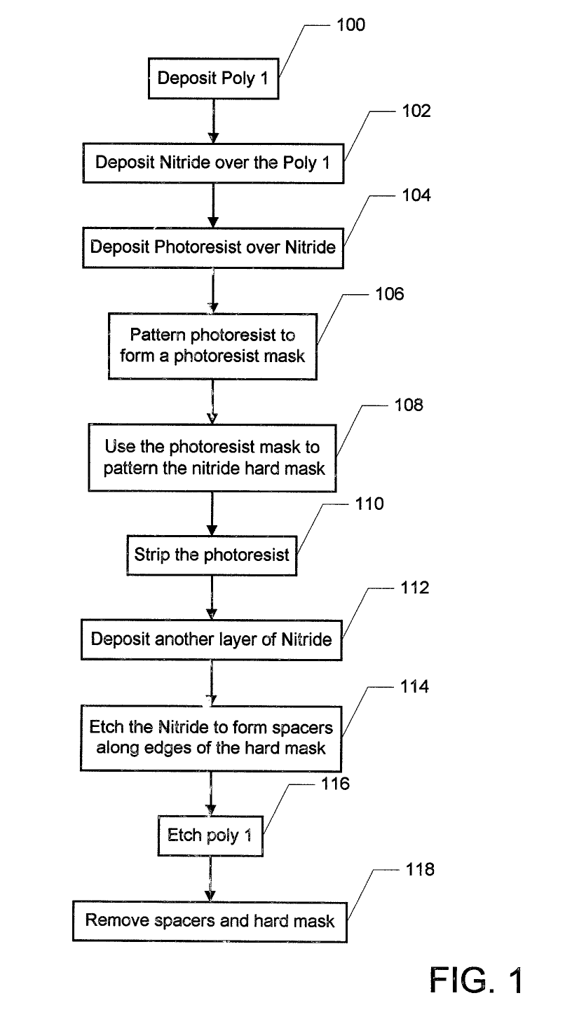

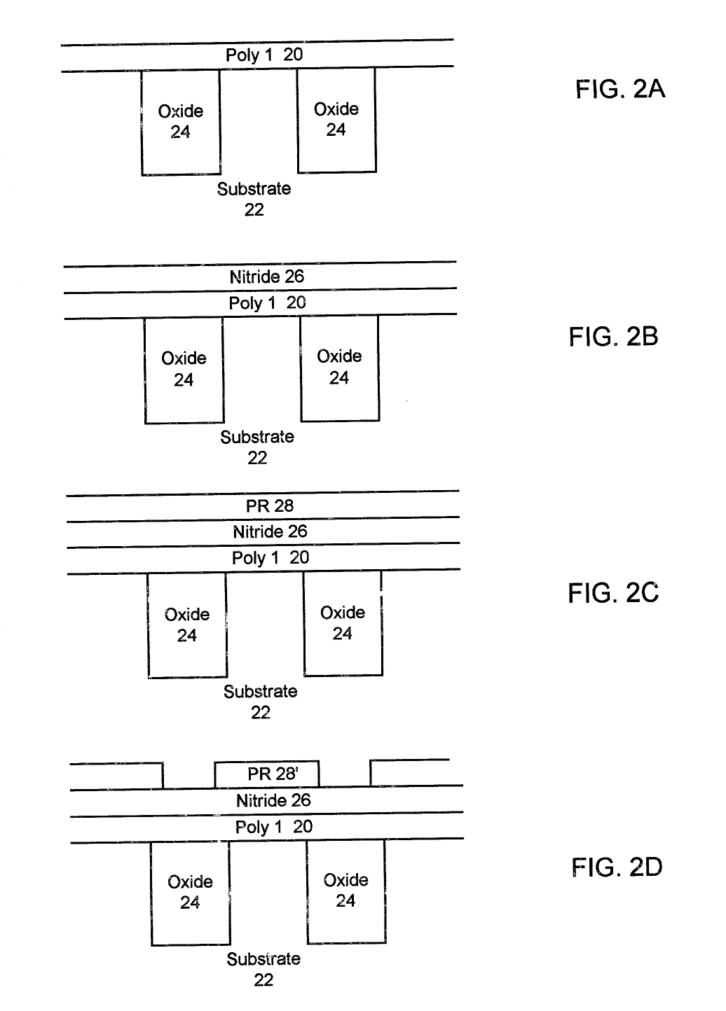

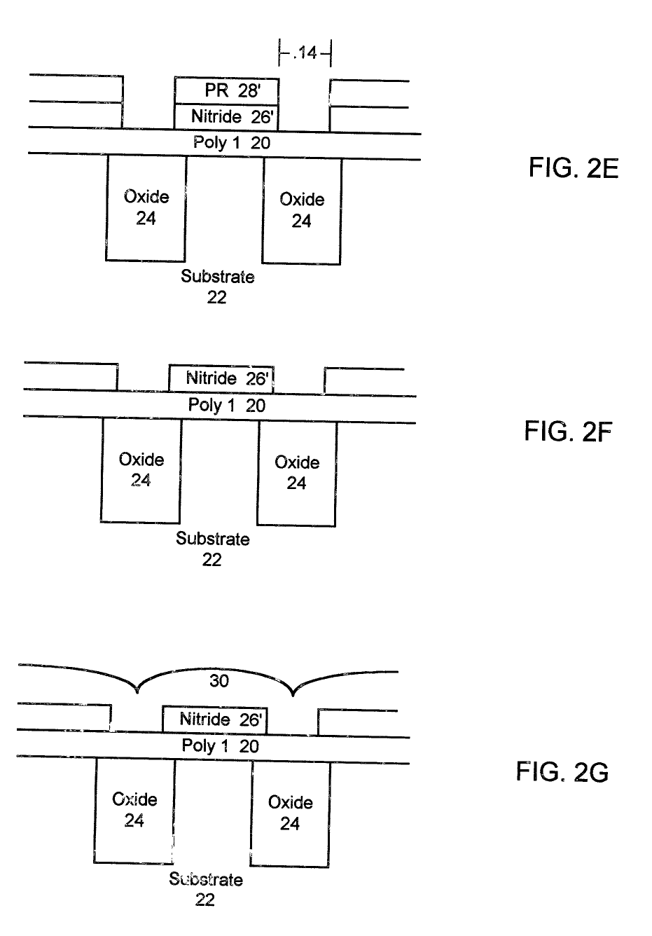

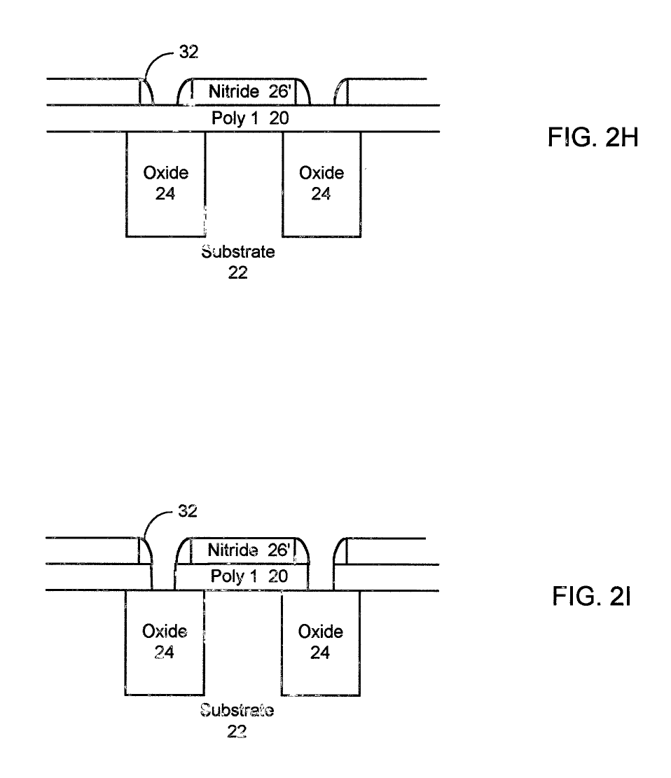

FIG. 1 is a flow chart illustrating the fabrication steps used to pattern Poly 1 into floating gates using a hard mask. FIGS. 2A-2I are cross-sectional views of the silicon substrate during the fabrication steps described in FIG. 1. The process begins by depositing a layer of Poly 1 20 over a silicon substrate 22 in step 100. As shown in FIG. 2A, the substrate 22 includes insulating regions of oxide 24, which are formed in-between active areas where transistors will be located.

After the Poly 1 has been deposited, a layer of nitride 26, or other such material, is deposited over the Poly 1 20 in step 102 to eventually form a hard mask (FIG. 2B). In a preferred embodiment, the nitride layer 26 is approximately 150-1500 angstroms thick. After the nitride 26 is deposited, a layer of photoresist 28 is deposited over the nitride 26 in step 104 (FIG. 2C). The photoresist 28 is then patterned in step 106 to form a photoresist mask 28′ (FIG. 2D). The photoresist mask 28′ is then used to pattern the nitride hard mask 26′ in step 108 (FIG. 2E). After the nitride hard mask 26′ has been patterned, the photoresist 28 is stripped in step 110 (FIG. 2F). What remains is a nitride hard mask 26′ having gaps that are no smaller than 0.14 microns due to the limits of lithography.

In order to create smaller gaps in the nitride hard mask 26′ that exceed the limits of lithography, another layer of nitride 30 (or other such material) is patterned over the nitride hard mask 26′ in step 112 (FIG. 2G). This layer of nitride 30 is then etched to form spacers 32 along the nitride edges in step 114 (FIG. 2H). After the spacers 32 are formed, the Poly 1 20 is etched using the spacers 32 and nitride 26 as a mask in step 116 to form lines of Poly 1 20 (FIG. 21). In a preferred embodiment, the spaces between the lines of Poly 1 20 are 0.08-0.05 microns, which exceed lithography limits.

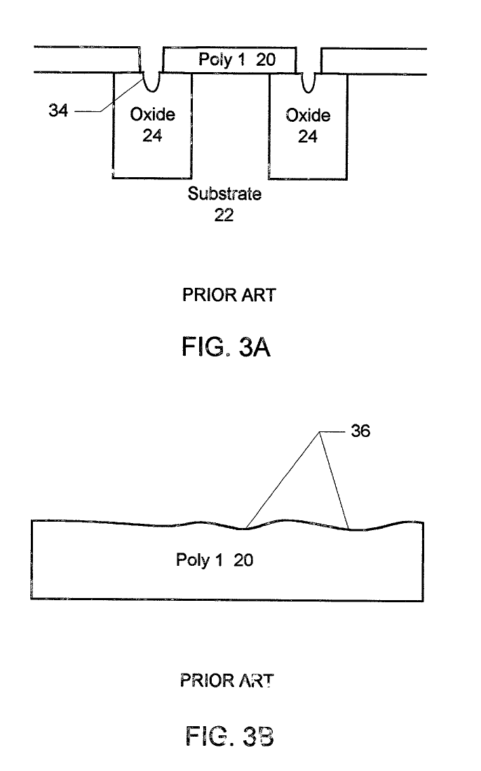

After the Poly 1 20 has been etched, the spacers 32 and nitride mask 28′ need to be removed in step 118. Conventional methods for removing the spacers 32 and hard mask 26′ include utilizing either a dry etch, or a wet etch. FIGS. 3A and 3B are cross-sectional views of the substrate 22 showing the results of a conventional dry and wet etch, respectively. As shown in FIG. 3A, if the spacers 32 and hard mask 26′ are removed using a dry etch, then the dry etch typically forms gouges 34 in the oxide 24.

Gouging of the oxide 24 may be avoided by performing a wet etch, using a solution of H3P04 for instance. As shown in FIG. 3B, although performing a wet etch avoids gouging, the wet etch solution typically erodes the Poly 1 20, causing pits 36 to form on the surface of the Poly 1 20. Both gouges 34 in the oxide 24 and pits 36 on the Poly 1 20 may degrade semiconductor performance.

According to the present invention, a two-step hard mask removal process is provided that combines a major wet etch with a minor dry etch that avoids the problems of gouging and pitting.

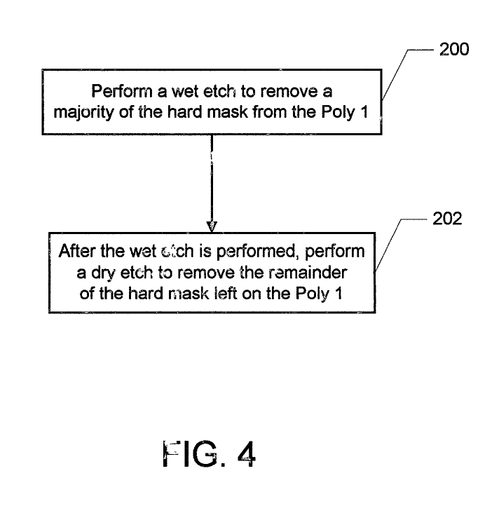

FIG. 4 is a flow chart illustrating the process of removing a hard mask (step 118) in accordance with a preferred embodiment of the present invention. The hard mask 28′ material is removed from the Poly 1 20 by performing a wet etch to remove a majority of the hard mask material 26′ in step 200. The time that the wet etch needs to be performed depends on the concentration of the wet etch solution and the thickness of the hard mask 26′. However, the hard mask 26′ should be exposed to the wet etch solution for a time sufficient to remove substantially all of the hard mask 26′. In a preferred embodiment, approximately 80-90% of the hard mask 26′ is removed. Leaving 10-20% of the hard mask 26′ on the surface of the Poly 1 20 prevents the wet etch solution from attacking the Poly 1 20.

After the wet etch is performed, a dry etch is performed to remove the remainder of the hard mask material 26′ left on the Poly 1 20 in step 202. As is well known in the art, the dry etch process may be stopped by time, or by an endpoint method that detects a change of material (i.e., the dry etch is stopped when the process detects that the material being etched changes from Poly 1 20 to silicon or oxide 24. Because only a remaining portion of the hard mask 26′ is removed by the dry etch (preferably 10-20%) gouging of the oxide 24 during the dry etch process is substantially eliminated.

Although the present invention has been described in terms of the preferred embodiment, those of ordinary skill in the art will readily recognize that the hard mask removal process may apply to any semiconductor process where a hard mask material is used to pattern another material and the hard mask needs to be removed.

A two-step hard mask removal process has been disclosed that includes a major wet etch followed by a minor dry etch. The present invention has been described in accordance with the embodiments shown, and one of ordinary skill in the art will readily recognize that there could be variations to the embodiments, and any variations would be within the spirit and scope of the present invention. Accordingly, many modifications may be made by one of ordinary skill in the art without departing from the spirit and scope of the appended claims.

What is claimed is:

1 A method for removing a hard mask during a semiconductor fabrication process in which a hard mask material is used to pattern a first material, the method comprising the steps of:
(a) performing a wet etch that removes a majority of the hard mask material; and
(b) performing a dry etch that removes a remainder of the hard mask material.

2 The method of claim 1 wherein step (a) further includes the step of performing the wet etch for a time sufficient to remove substantially all of the hard mask material, such that the remainder of the hard mask material protects the first material from a wet at solution.

3 The method of claim 2 wherein step (a) further includes the step of performing the wet etch to remove approximately 80-90% of the hard mask material.

4 The method of claim 3 wherein step (a) further includes the step of leaving approximately 10-20% of the hard mask material on the surface of the first material to prevent the wet etch from damaging the first material.

5 The method of claim 2 wherein the first material is patterned over a substrate that includes a third material therein, step (b) further including the step of performing the dry etch on the remainder of the hard mask material, such that gouging of the third material in the substrate is substantially eliminated.

6 The method of claim 5 further including step of performing the hard mask removal during fabrication of a flash memory array in which the hard mask has been patterned on top of a layer of polysilicon that is deposited over a silicon substrate.

7 The method of claim 6 further including step of providing nitride as the hard mask.

8 The method of claim 7 further including the step of providing oxide as the third material.

9 A method of removing a hard mask during a semiconductor process, the method comprising the steps of:
(a) depositing a layer of polysilicon over a substrate that includes insulating regions;
(b) patterning a hard mask over the layer of polysilicon;
(c) forming spacers along the edges of the hard mask;
(d) using the spacers and the hard mask to pattern the polysilicon; and
(e) removing the spacers and hard mask by,
(i) performing a wet etch that removes a majority of the spacers and the hard mask, such that pitting of the polysilicon by the wet etch is avoided, and
(ii) performing a dry etch that removes a remainder of the hard mask material, such that gouging of the insulating regions by the dry etch is substantially eliminated.

10 The method of claim 9 further comprising the steps of using nitride as the hard mask.

11 The method of claim 10 further comprising the steps of patterning the polysilicon such that the polysilicon includes gaps of approximately 0.08-0.05 microns.

12 The method of claim 10 wherein step (e)(i) further includes a step of performing the wet etch for a time sufficient to remove substantially all of the hard mask.

13 The method of claim 12 wherein step (e)(i) further includes step of performing the wet etch to remove approximately 80-90% of the hard mask.
